(19) United States
(12) Patent Application Publication
(10) Pub. No.: US 2012/0178232 A1
(43) Pub. Date: Jul. 12, 2012

(54) FIELD EFFECT DEVICE STRUCTURE INCLUDING SELF-ALIGNED SPACER SHAPED CONTACT

(75) Inventor: Huilong Zhu, Poughkeepsie, NY (US)

(73) Assignee: International Business Machines Corporation, Armonk, NY (US)

(21) Appl. No.: 13/427,257

(22) Filed: Mar. 22, 2012

Related U.S. Application Data
(62) Division of application No. 12/039,063, filed on Feb. 28, 2008.

(51) Int. Cl. H01L 21/336

(52) U.S. Cl. 438/303; 257/E21.433

(57) ABSTRACT

A semiconductor structure and a method for fabricating the semiconductor structure include or provide a field effect device that includes a spacer shaped contact via. The spacer shaped contact via comprises a spacer shaped annular contact via that is located surrounding and separated from an annular spacer shaped gate electrode at the center of which may be located a non-annular and non-spacer shaped second contact via. The annular gate electrode as well as the annular contact via and the non-annular contact via may be formed sequentially in a self-aligned fashion while using a single sacrificial mandrel layer.

### CROSS REFERENCE TO RELATED APPLICATION

This application is a divisional of U.S. patent application Ser. No. 12/039,063, filed Feb. 28, 2008 the entire content and disclosure of which is incorporated herein by reference.

### BACKGROUND

1. Field of the Invention

The invention relates generally to semiconductor structures. More particularly, the invention relates to semiconductor structures with enhanced manufacturability.

2. Description of the Related Art

Semiconductor structures include semiconductor devices that are located within and/or upon a semiconductor substrate. The semiconductor devices are connected and interconnected over the semiconductor substrate while using patterned conductor layers that are separated by dielectric layers.

Although semiconductor devices within semiconductor circuits may include active semiconductor devices, such as but not limited to transistors and diodes, as well as passive devices, such as but not limited to resistors and capacitors, a particularly common active semiconductor device is a field effect transistor. Field effect transistors have been effectively and successfully scaled in dimension over the period of several decades.

While field effect transistors are quite common in the semiconductor fabrication art, field effect transistors are nonetheless not entirely without problems as semiconductor device and structure dimensions have decreased. In particular, as semiconductor device and structure dimension have decreased, it generally becomes more difficult to fabricate properly aligned contacts within semiconductor structures.

Semiconductor device and semiconductor structure dimensions are certain to continue to decrease. Thus, desirable within semiconductor fabrication are semiconductor structures and methods for fabrication thereof that provide for proper and effective alignment of contact structures to semiconductor device contact regions.

### SUMMARY OF THE INVENTION

The invention provides a semiconductor structure and a method for fabricating the semiconductor structure. A semiconductor structure in accordance with the invention includes a spacer shaped contact via located upon a source/drain region within a field effect device that in part comprises the semiconductor structure in accordance with the invention. A method for fabricating the semiconductor structure provides that the spacer shaped contact via is formed in a self-aligned fashion with respect, ultimately, to a gate electrode to which is also formed in a self-aligned fashion a source/drain region. A “spacer shaped contact via” is intended as a contact via having three sides, two of which are nominally planar and intersect perpendicularly, and the third of which curves outwardly to connect to the other two sides. Such a spacer shaped contact via will thus normally have a pointed upper tip.

A particular semiconductor structure in accordance with the invention includes a gate electrode located over a channel region within a semiconductor substrate that separates a pair of source/drain regions within the semiconductor substrate. This particular semiconductor structure also includes a spacer shaped contact via located upon one of the source/drain regions and electrically isolated from the gate electrode.

Another particular semiconductor structure in accordance with the invention includes an annular spacer shaped gate electrode located at least in part over a channel region within a semiconductor substrate that separates a pair of source/drain regions within the semiconductor substrate. This particular semiconductor structure also includes an annular spacer shaped contact via located at least in part upon one of the source/drain regions, the annular spacer shaped contact via surrounding and being electrically isolated from the gate electrode. Within this particular semiconductor structure, the “annular” spacer shaped gate electrode, or the “annular” spacer shaped contact via, are intended as ring shaped structures that are not necessarily circular in a projected shape.

A particular method for fabricating a semiconductor structure in accordance with the invention includes forming a gate electrode annularly surrounding a sacrificial layer located over a semiconductor substrate. This particular method also includes removing the sacrificial layer from over the semiconductor to leave remaining the annular gate electrode. This particular method also includes forming a first source/drain region within the semiconductor substrate outside of the annular gate electrode and a second source/drain region inside the annular gate electrode. This particular method also includes forming an annular contact via contacting the first source/drain region and surrounding the annular gate electrode.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, that form a material part of this disclosure, wherein:

FIG. 1 to FIG. 13B show a series of schematic cross-sectional and plan-view diagrams illustrating the results of progressive stages in fabricating a semiconductor structure in accordance with a preferred embodiment of the invention.

### DESCRIPTION OF THE PREFERRED EMBODIMENT

The invention, which includes a semiconductor structure that includes a spacer shaped contact via, as well as a method for fabricating the semiconductor structure that includes the spacer shaped contact via, is understood within the context of the description set forth below. The description set forth below is understood within the context of the drawings described above. Since the drawings are intended for illustrative purposes, the drawings are not necessarily drawn to scale.

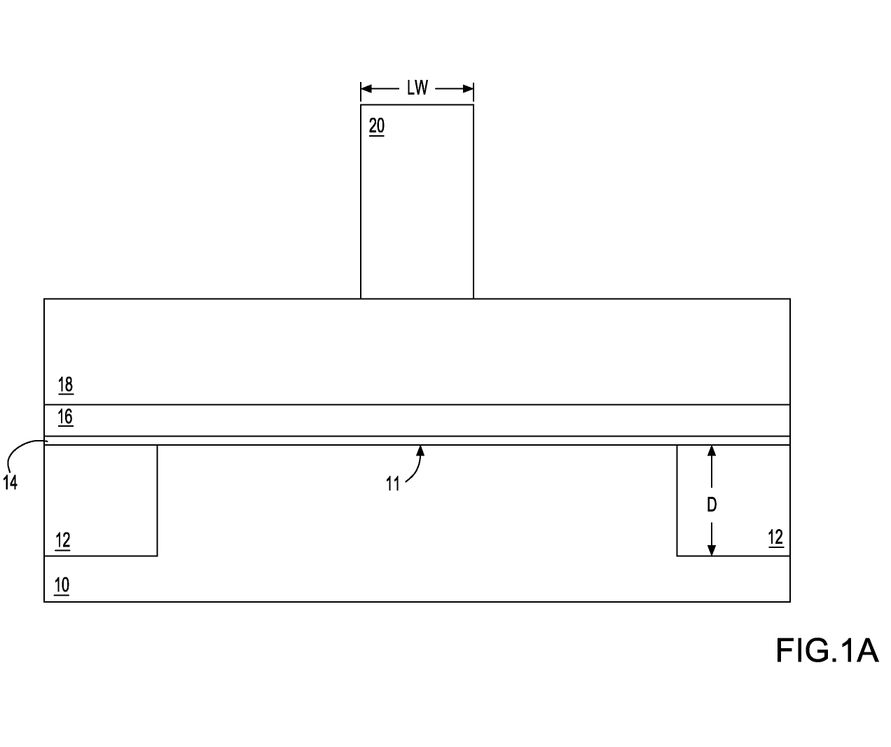

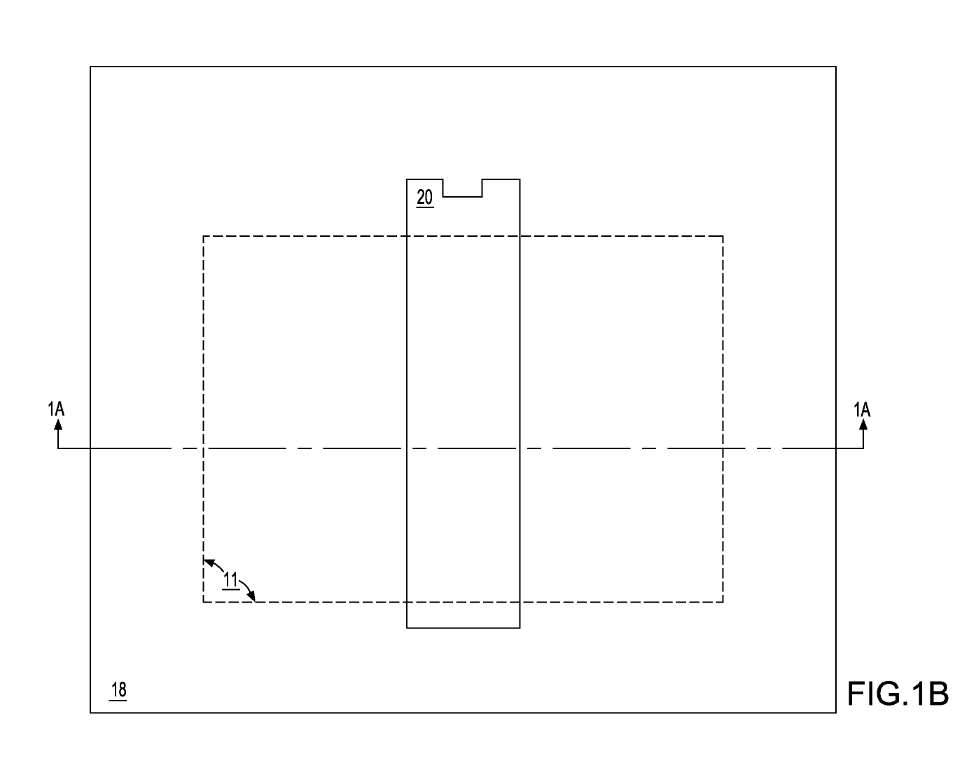

FIG. 1 to FIG. 13B show a series of schematic cross-sectional and plan-view diagrams illustrating the results of progressive stages in fabricating a semiconductor structure in accordance with a particular embodiment of the invention. This particular embodiment of the invention comprises a sole preferred embodiment of the invention. FIG. 1 shows a schematic cross-sectional diagram illustrating the semiconductor structure at an early stage in the fabrication thereof in accordance with the sole preferred embodiment.

FIG. 1A and FIG. 1B show a semiconductor substrate 10 that includes an active region 11 that is defined within an isolation region 12 that is embedded within the semiconductor substrate 10.

The semiconductor substrate 10 may comprise any of several semiconductor materials. Non-limiting examples include silicon, germanium, silicon-germanium alloy, silicon-carbon alloy, silicon-germanium-carbon alloy and compound (i.e., III-V and II-VI) semiconductor materials. Non-limiting examples of compound semiconductor materials include gallium arsenide, indium arsenide and indium phosphide semiconductor materials. Typically, the semiconductor substrate 10 has a thickness from about 1 to about 3 mm.

The isolation region 12 may comprise any of several dielectric materials. Non-limiting examples include oxides, nitrides and oxynitrides, particularly of silicon, but oxides, nitrides and oxynitrides of other elements are not excluded. The isolation region 12 may comprise a crystalline or a non-crystalline dielectric material, with crystalline dielectrics being highly preferred. The isolation region 12 may be formed using any of several methods. Non-limiting examples include ion implantation methods, thermal or plasma oxidation or nitridation methods, chemical vapor deposition methods and physical vapor deposition methods. Typically, the isolation region 12 comprises an oxide of the semiconductor material from which is comprised the semiconductor substrate 10. Typically, the isolation region 12 has a depth D from about 1000 to about 7000 angstroms within the semiconductor substrate 10.

While the preferred embodiment illustrates the invention within the context of a bulk semiconductor substrate as the semiconductor substrate 10, neither the embodiment nor the invention is intended to be so limited. Rather the embodiment and the invention contemplate in place of a bulk semiconductor substrate as the semiconductor substrate 10 either a semiconductor-on-insulator substrate or a hybrid orientation substrate.

A semiconductor-on-insulator substrate may result from incorporation of a buried dielectric layer interposed between a base semiconductor substrate and a surface semiconductor layer within a bulk semiconductor substrate. A hybrid orientation substrate includes multiple semiconductor regions of different orientation located and supported over a single substrate that is typically a single semiconductor substrate.

Semiconductor-on-insulator substrates and hybrid orientation substrates may be fabricated using any of several methods. Non-limiting examples include lamination methods, layer transfer methods and separation by implantation of oxygen (SIMOX) methods.

FIG. 1A also shows (in cross-section): (1) a gate dielectric 14 located upon the active region 11 of the semiconductor substrate 10 and the isolation region 12; (2) a gate material layer 16 located upon the gate dielectric 14; (3) a sacrificial layer 18 located upon the gate material layer 16; and (4) a photoresist layer 20 located upon the sacrificial layer 18. Each of the foregoing layers may also be formed using methods that are conventional in the semiconductor fabrication art.

The gate dielectric 14 may comprise conventional dielectric materials such as oxides, nitrides and oxynitrides of silicon that have a dielectric constant from about 4 to about 20, measured in vacuum. Alternatively, the gate dielectric 14 may comprise generally higher dielectric constant dielectric materials having a dielectric constant from about 20 to at least about 100. Such higher dielectric constant dielectric materials may include, but are not limited to hafnium oxides, hafnium silicates, titanium oxides, barium-strontium-titantates (BSTs) and lead-zirconate-titanates (PZTs). The gate dielectric 14 may be formed using any of several methods that are appropriate to its material(s) of composition. Included, but not limiting are thermal or plasma oxidation or nitridation methods, chemical vapor deposition methods and physical vapor deposition methods. Typically, the gate dielectric 14 comprises a higher dielectric constant dielectric material, such as but not limited to a hafnium oxide or a hafnium silicate, that has a thickness from about 2 to about 5 nanometers.

The gate material layer 16 may comprise materials including, but not limited to certain metals, metal alloys, metal nitrides and metal silicides, as well as laminates thereof and composites thereof. The gate material layer 16 may also comprise doped polysilicon and doped polysilicon-germanium alloy materials (i.e., having a dopant concentration from about 1e18 to about 1e22 dopant atoms per cubic centimeter) and polycide materials (doped polysilicon/metal silicide stack materials). Similarly, the foregoing materials may also be formed using any of several methods. Non-limiting examples include salicide methods, chemical vapor deposition methods and physical vapor deposition methods, such as, but not limited to evaporative methods and sputtering methods. Typically, the gate material layer 16 comprises a metal gate material, such as but not limited to a titanium nitride or a tantalum nitride, that has a thickness from about 5 to about 20 nanometers.

The sacrificial layer 18 may comprise any of several sacrificial materials given the proviso that the sacrificial layer 18 comprises a sacrificial material that has an etch selectivity with respect to materials that comprise the layers that surround the sacrificial layer 18. Dielectric sacrificial materials are most common, but by no means limit the embodiment or the invention. The dielectric sacrificial materials may include, but are not limited to oxides, nitrides and oxynitrides of silicon, but oxides, nitrides and oxynitrides of other elements are not excluded. The dielectric sacrificial materials may be formed using any of the several methods that may be used for forming the isolation regions 12. Typically, the sacrificial layer 18 comprises a silicon nitride dielectric material that has a thickness from about 50 to about 150 nanometers.

The photoresist layer 20 may comprise any of several photoresist materials. Non-limiting examples include positive photoresist materials, negative photoresist materials and hybrid photoresist materials that exhibit properties of positive photoresist materials and negative photoresist materials. Typically, the photoresist layer 20 has a linewidth LW from about 30 to about 200 nanometers and a thickness from about 100 to about 500 nanometers.

FIG. 1B shows a schematic plan-view diagram of a semiconductor structure corresponding with the semiconductor structure whose schematic cross-sectional diagram is illustrated in FIG. 1A.

FIG. 1B shows the sacrificial layer 18 beneath which is the outline of the active region 11 and above which is the photoresist layer 20.

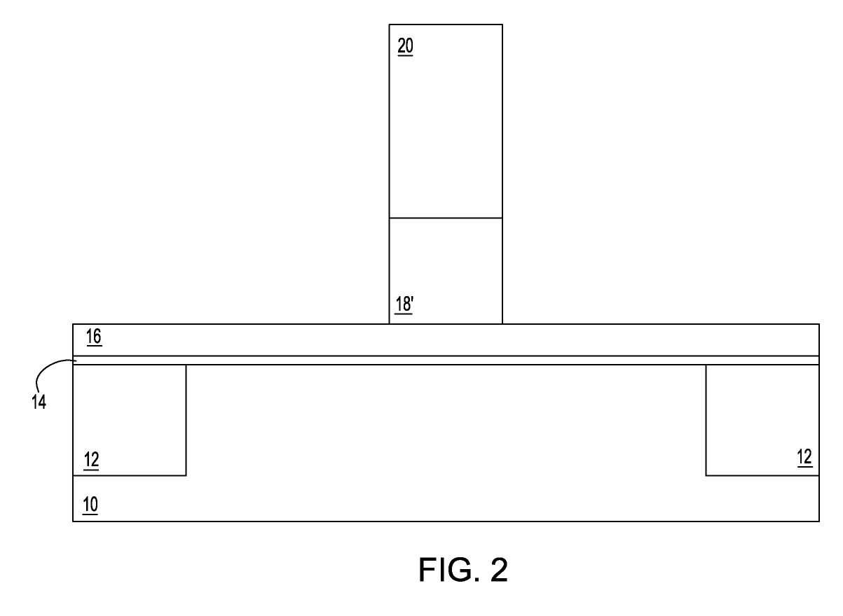

FIG. 2 shows a sacrificial layer 18′ that results from patterning the sacrificial layer 18 that is illustrated in FIG. 1A, while using the photoresist layer 20 as an etch mask layer. The foregoing patterning and etching may be affected while using methods and materials that are generally conventional in the semiconductor fabrication art. Included in particular are wet chemical etch methods and dry plasma etch methods. Dry plasma etch methods are generally more common insofar as dry plasma etch methods generally provide straight sidewalls to the sacrificial layer 18′. A particular plasma etch method for forming the sacrificial layer 18′ from the sacrificial layer 18 uses an etchant gas composition appropriate to the material from which is comprised the sacrificial layer 18.

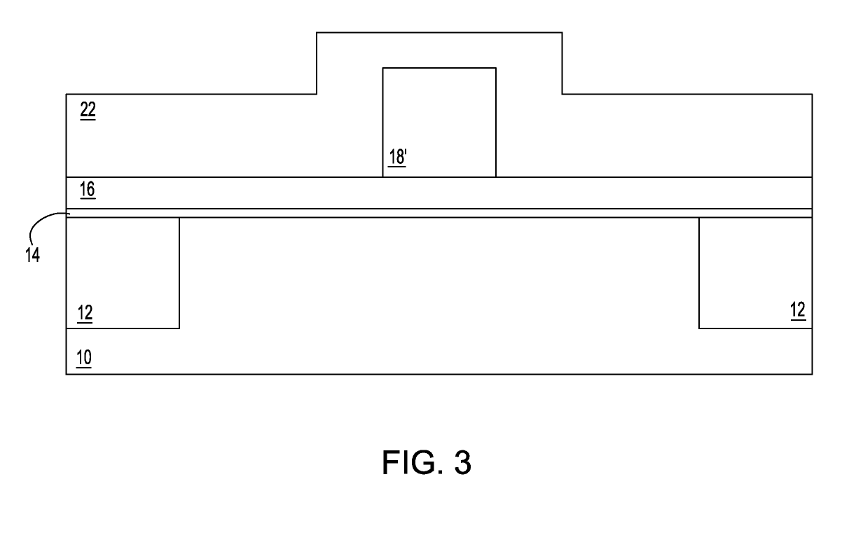

FIG. 3 first shows the results of stripping the photoresist layer 20 from the sacrificial layer 18′ within the schematic cross-sectional diagram of FIG. 2. The photoresist layer 20 may be stripped using methods and materials that are generally conventional in the semiconductor fabrication art. Included in particular are wet chemical stripping methods, dry plasma stripping methods and combinations of wet chemical stripping methods and dry plasma stripping methods.

FIG. 3 also shows a supplemental gate material layer 22 located and formed upon the semiconductor structure of FIG. 2 after stripping from the sacrificial layer 18′ therein the photoresist layer 20. The supplemental gate material layer 22 may comprise any of the several gate materials from which may be comprised the gate material layer 16. Typically the supplemental gate material layer 22 comprises a polysilicon or polysilicon-germanium gate material when the gate material layer 16 comprises a metal gate material. Typically, the supplemental gate material layer 22 has a thickness from about 15 to about 40 nanometers.

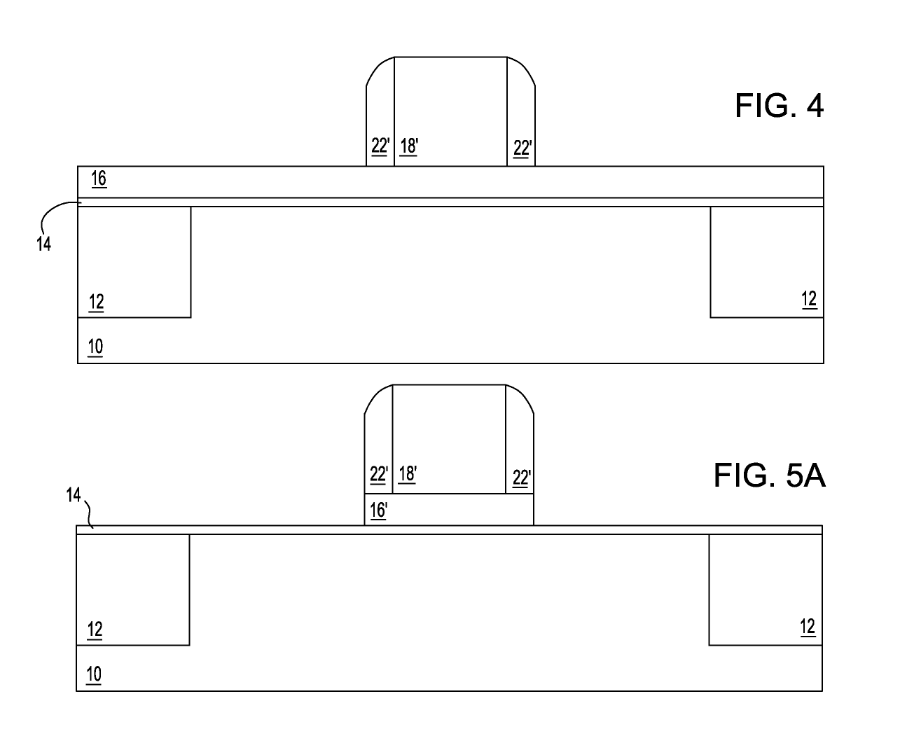

FIG. 4 shows the results of ansiotropically etching the supplemental gate material layer 22 that is illustrated in FIG. 3 to provide a spacer shaped gate electrode 22′ that in accordance with a plan-view diagram discussed in further detail below encircles the sacrificial material layer 18′. The foregoing anisotropic etching is effected using an etchant gas composition appropriate to the material from which is comprised the supplemental gate material layer 22 that is illustrated in FIG. 3.

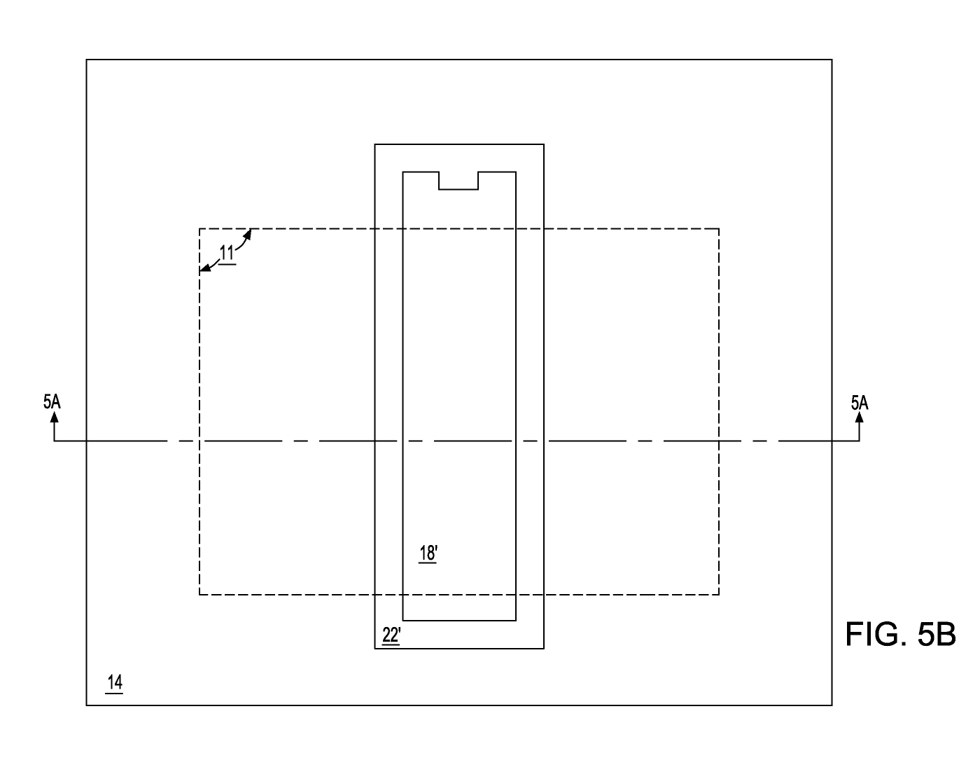

FIG. 5A shows a gate material layer 16′ that results from etching the gate material layer 16 that is illustrated in FIG. 4, while using the sacrificial layer 18′ and the supplemental gate material layer 22′ as a mask. The foregoing etching is typically effected while employing an anisotropic plasma etch method that uses an etchant gas composition that is appropriate to the material from which is comprised the gate material layer 16.

FIG. 5B shows a schematic plan-view diagram that corresponds with the schematic cross-sectional diagram of FIG. 5A.

FIG. 5B illustrates the gate dielectric 14 beneath which is the outline of the active region 11 and above which is an annular supplemental gate material layer 22′ that annularly surrounds the sacrificial layer 18′.

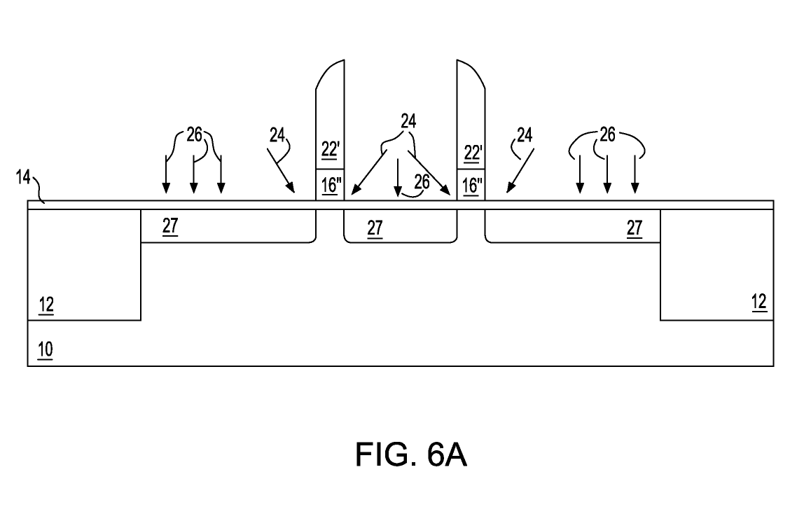

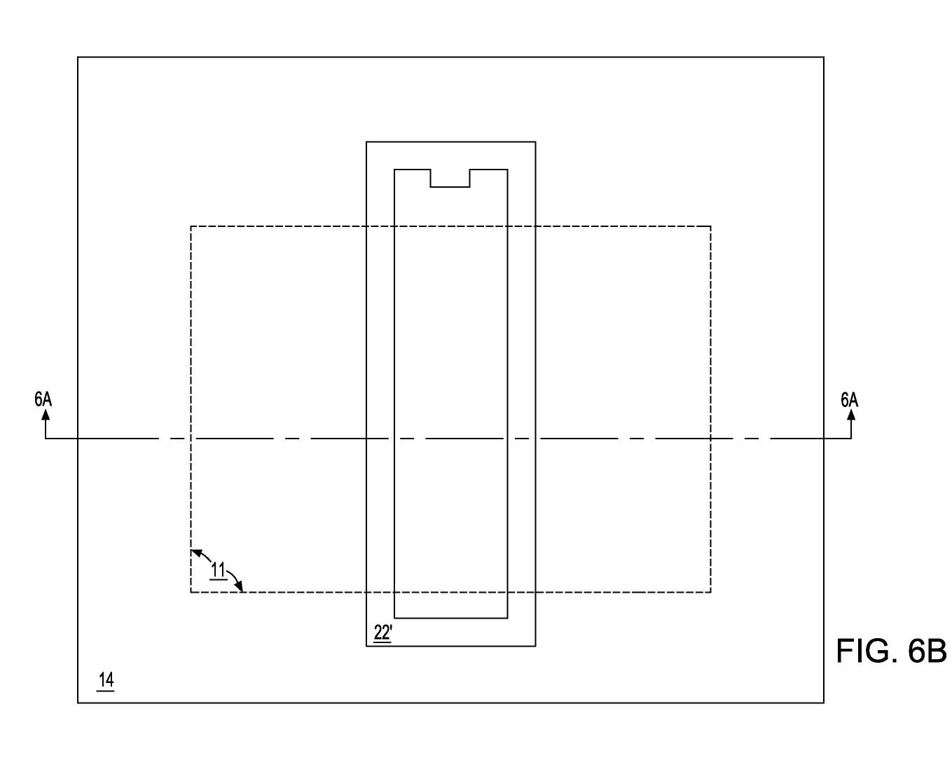

FIG. 6A first shows the results of stripping the sacrificial layer 18′ from the semiconductor structure of FIG. 5A and FIG. 5B. The sacrificial layer 18′ may be stripped from the semiconductor structure of FIG. 5A to provide in part the semiconductor structure of FIG. 6A while using stripping methods and materials that are appropriate to the material(s) from which is comprised the sacrificial layer 18′. Such methods and materials may include, but are not necessarily limited to wet chemical stripping methods and dry plasma stripping methods.

FIG. 6A next shows the results of etching the gate material layer 16′ to form a gate material layer 16″, while using the supplemental gate material layer 22′ as a mask and the gate dielectric 14 as an etch stop layer. This particular foregoing etching to provide the gate material layer 16″ may also be effected using methods and materials that are generally conventional in the semiconductor fabrication art. Included in particular, but not limiting are wet chemical etch methods and dry plasma etch methods.

FIG. 6A finally shows a dose of halo implanting ions 24 and a dose of extension implanting ions 26 each of which is implanted into the active region of the semiconductor substrate 10 while using the gate material layer 16″ and the supplemental gate material layer 22′ as a mask. In an aggregate, the gate material layer 16″ and the supplemental gate material layer 22′ comprise a gate electrode within a field effect device that is formed incident to further fabrication of the semiconductor structure of FIG. 6A. FIG. 6A also shows a series of extension regions 27 that result from implanting of the extension implanting ions 26. The halo implanting ions 24 and the extension implanting ions 26 are of appropriate polarity, dose and energy for a particular polarity of a field effect device desired to be fabricated.

FIG. 6B shows a schematic plan-view diagram that corresponds with the schematic cross-sectional diagram of FIG. 6A. FIG. 6B shows the gate dielectric 14 beneath which is the outline of the active region 11 and above which is the supplemental gate material layer 22′ which in conjunction with the gate material layer 16″ thereunder comprises an annular gate electrode that does not at this point in the fabrication of the semiconductor structure whose schematic plan view diagram is illustrated in FIG. 6B encircle any additional structure.

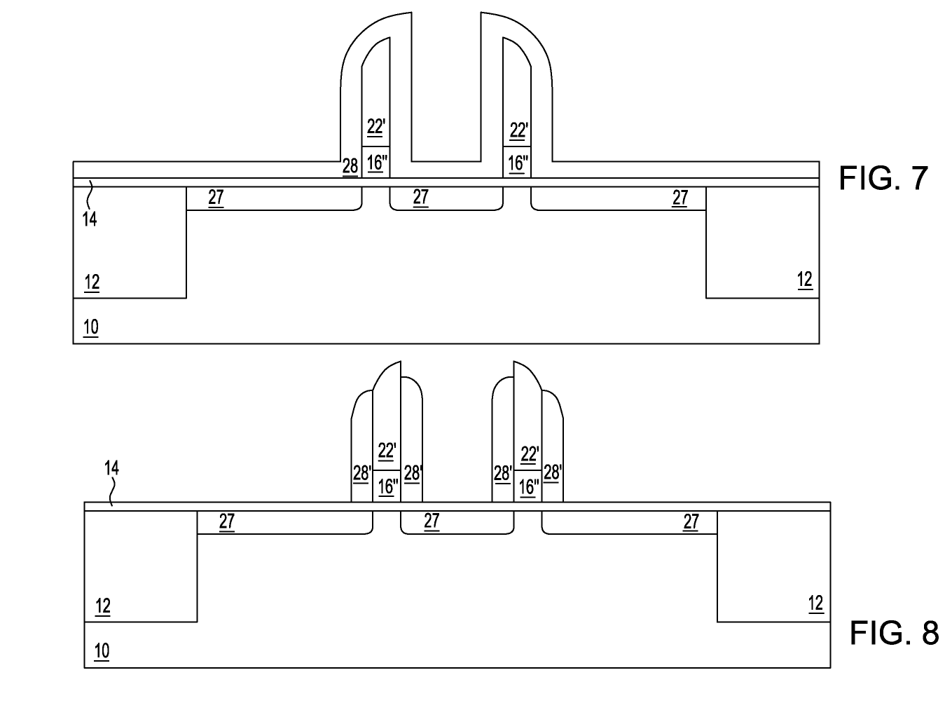

FIG. 7 shows a spacer material layer 28 located and formed upon the semiconductor structure whose schematic cross-sectional diagram is illustrated in FIG. 6A and whose schematic plan-view diagram is illustrated in FIG. 6B.

The spacer material layer 28 typically comprises a dielectric spacer material, although the embodiment and the invention are not necessarily so limited. Typically such a dielectric spacer material may be selected from the same group of dielectric materials, and be formed using the same methods as used for forming, the isolation region 12. Typically, the spacer material layer 28 comprises at least one of a silicon oxide material and a silicon nitride material that has a thickness from about 10 to about 30 nanometers.

FIG. 8 shows the result of anisotropically etching the spacer material layer 28 that is illustrated within FIG. 7 to form a plurality of spacers 28′ annularly in plan-view located adjoining an inner sidewall and an outer sidewall of the gate electrode that comprises the gate material layer 16″ and the supplemental gate material layer 22′.

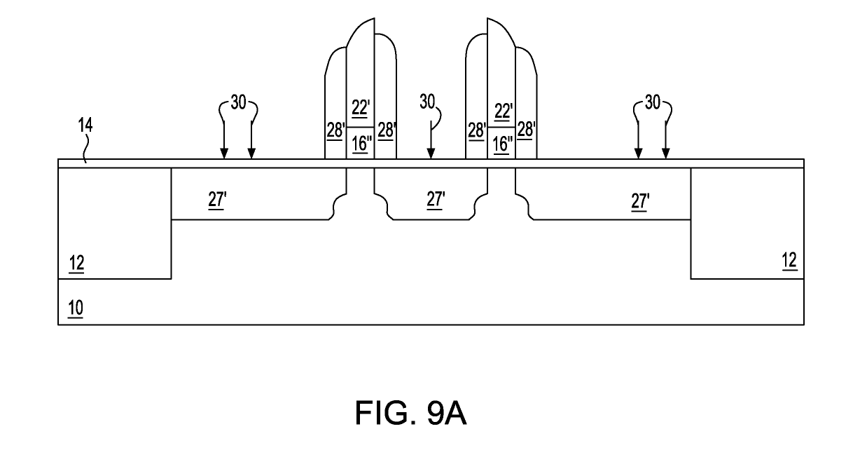

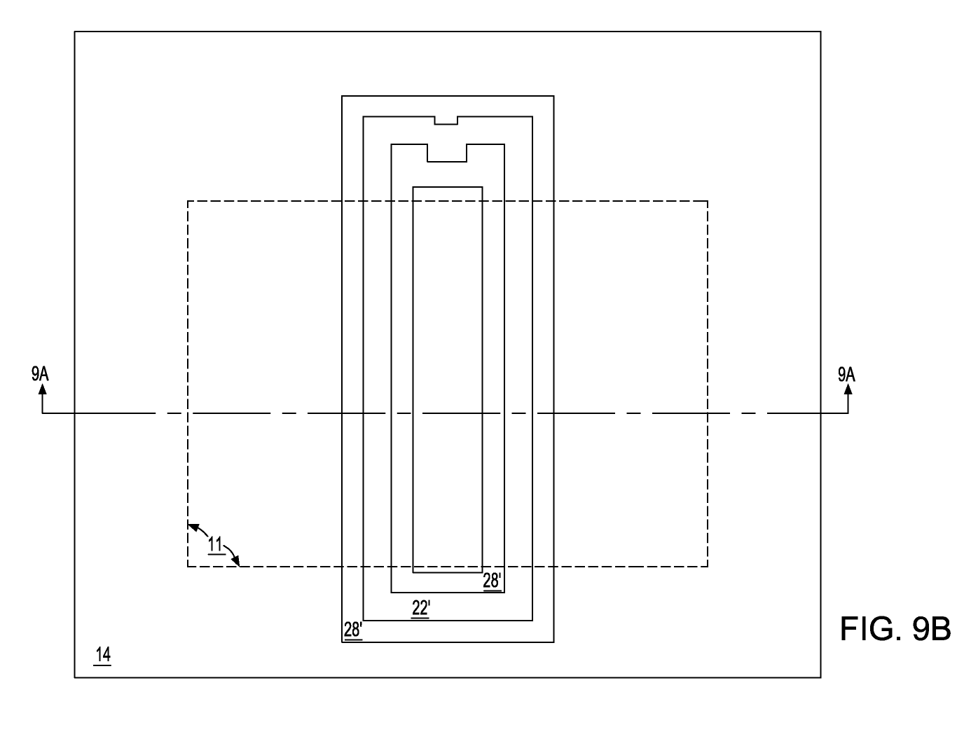

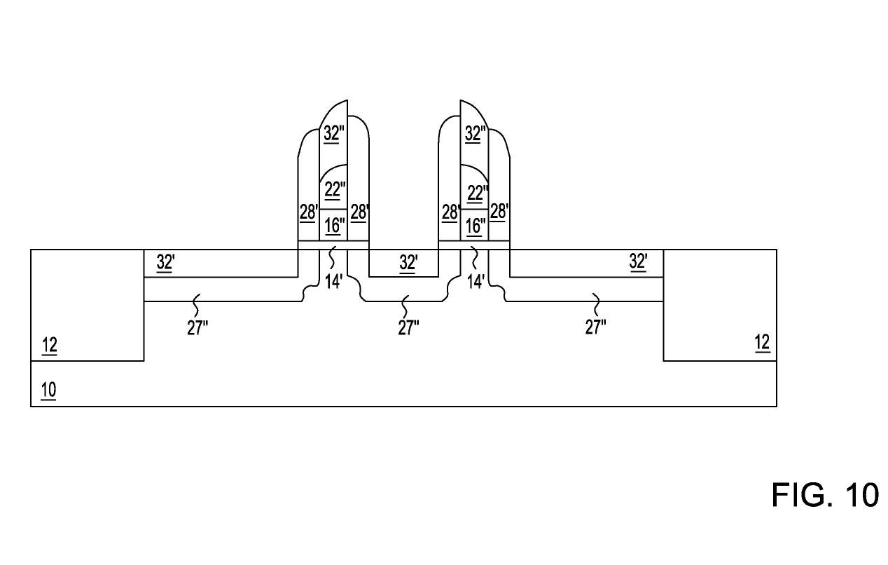

FIG. 9A shows the results of implanting the semiconductor structure of FIG. 8 while using a dose of source/drain region implanting ions 30 in conjunction with the gate material layer 16″, the supplemental gate material layer 22′ and the spacers 28′ as a mask to form source/drain regions 27′ into the semiconductor substrate 10 that incorporate the extension regions 27. The source/drain implanting ions 30 are typically of the same polarity as the extension implanting ions that are illustrated in FIG. 5, but not necessarily of the same concentration.

FIG. 9B shows a schematic plan-view diagram that corresponds with the schematic cross- sectional diagram of FIG. 9A. FIG. 9B shows the gate dielectric 14. An outline of the active region 11 is beneath the gate dielectric 14. Above the gate dielectric 14 is the annular gate electrode that comprises the gate material layer 16″ and the supplemental gate material layer 22′, that is sandwiched between the spacers 28′.

FIG. 10 shows the results of further processing of the semiconductor structure whose schematic cross-sectional diagram is illustrated in FIG. 9A.

FIG. 10 first shows the results of patterning the gate dielectric 14 to form a plurality of gate dielectrics 14′ that leave exposed the source/drain regions 27′ while using the spacers 28′, the gate material layers 16″ and the supplemental gate material layers 22′ that are illustrated in FIG. 9A as a mask. Such patterning may be effected using etch methods and etch materials that are otherwise generally conventional in the semiconductor fabrication art. Although such etch methods may include wet chemical etch methods and dry plasma etch methods, dry plasma etch methods are desirable to avoid undercutting of the gate dielectrics 14′.

FIG. 10 also shows: (1) silicide layers 32′ located and formed within and upon a plurality of source/drain regions 27″ that result from consumption of the source/drain regions 27′ that are illustrated in FIG. 9A; and (2) silicide layers 32″ located and formed upon a plurality of supplemental gate material layers 22″ that result from partial consumption of the supplemental gate material layers 22′.

Although not in general a limiting feature of the invention, the silicide layers 32′ and 32″ are formed using a salicide method. Candidate silicide materials include nickel, cobalt, titanium, tantalum, platinum and tungsten silicides, although the instant embodiment is not so limited. Typically, the silicide layers 32′ and 32″ comprise a nickel silicide material that has a thickness from about 100 to about 300 angstroms.

FIG. 11 shows a contact material layer 34 located and formed upon the semiconductor structure of FIG. 10.

The contact material layer 34 may comprise any of several contact materials. Aluminum, copper tungsten, tantalum, titanium and related nitride and alloy contact materials are common. Other conductor contact materials are not excluded. Most typically, the contact material layer 34 comprises a tungsten conductor contact material along with suitable conductor barrier materials. Typically the contact material layer 34 has a thickness from about 20 to about 100 nanometers.

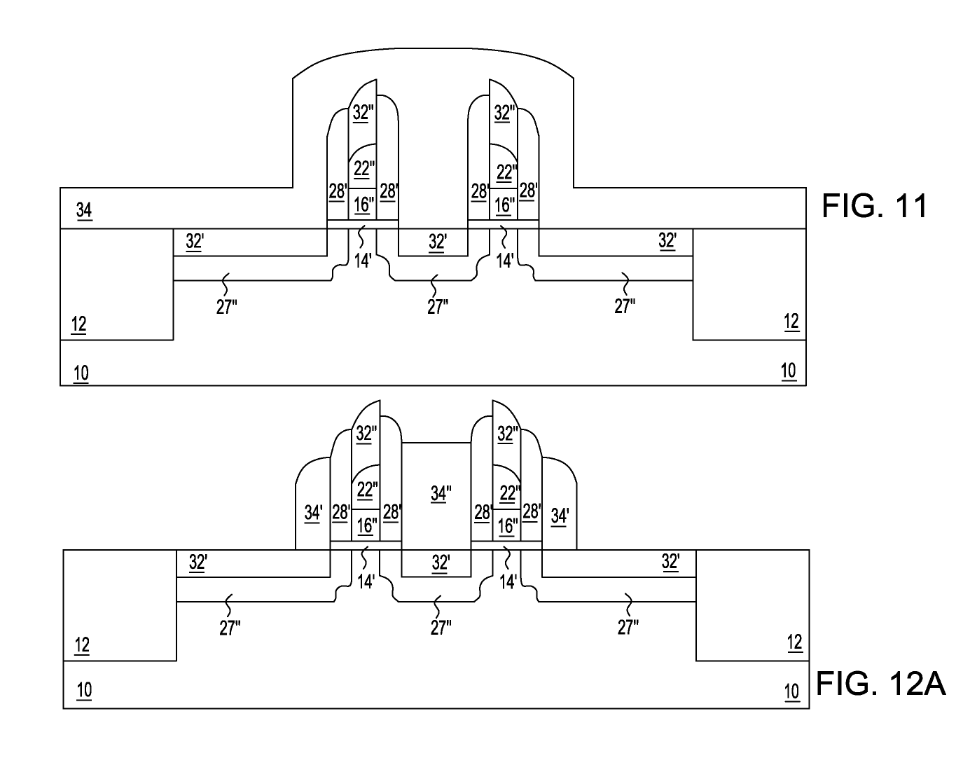

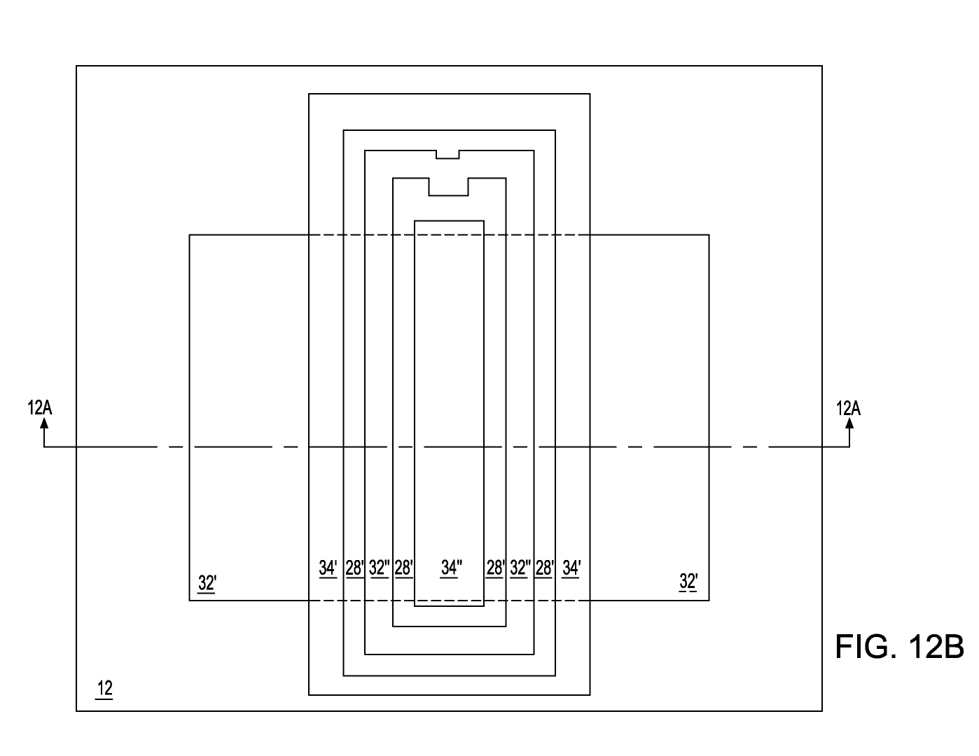

FIG. 12A shows the results of anisotropically etching the contact material layer 34 to form a contact material layer 34′ that serves as a spacer shaped contact via to peripheral source/drain regions 27′ and a filler conductor via 34″ with respect to the central source/drain region 27′.

The foregoing anisotropic etching is otherwise generally analogous or equivalent to the etching that is used for forming the spacers 28′, but the etching may use a different etchant gas composition in light of the materials differences between the spacers 28′ and the conductor contact material from which is comprised the contact material layer 34.

FIG. 12B shows a schematic plan-view diagram that corresponds with the schematic cross-sectional diagram of FIG. 12A. FIG. 12B shows the isolation region 12 and the silicide layers 32′ located upon the source/drain regions. FIG. 12B further illustrates the contact vias 34′ and 34″ that sandwich a pair of spacers 28′ that in turn sandwich a gate electrode that comprises the silicide layer 32″, the supplemental gate material layer 22″ and the gate material layer 16″ and is located over the active region 11 of the semiconductor substrate 10 and the isolation region 12.

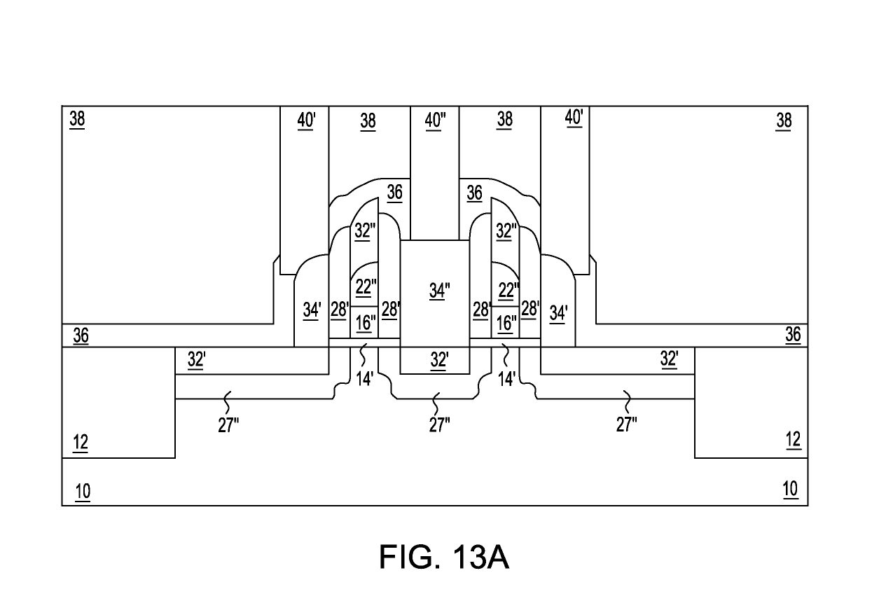

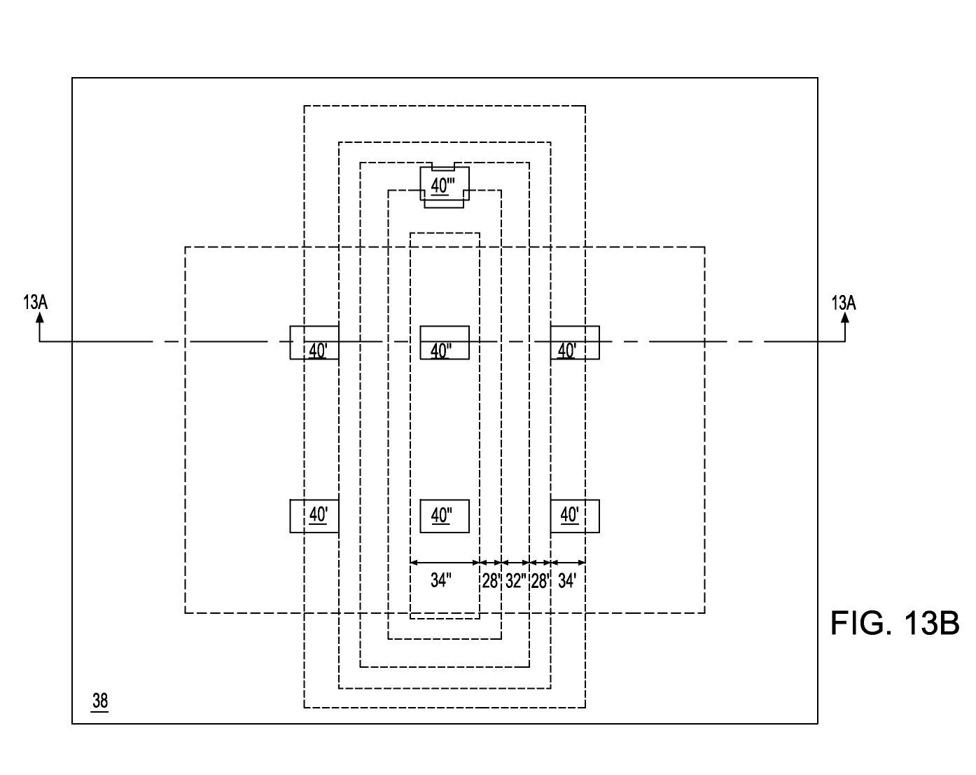

FIG. 13A shows a capping layer 36 located upon the semiconductor structure of FIG. 12A and FIG. 12B. The capping layer 36 may comprise any of several capping materials. Such capping materials will typically comprise dielectric capping materials.

FIG. 13A also shows an inter-level dielectric layer 38 located and formed upon the capping layer 36.

FIG. 13A finally shows supplemental contact vias 40′ and 40″ located and formed to contact the corresponding contact vias 34′ and 34″. The supplemental contact vias 40′ and 40″ are formed to contact the corresponding vias 34′ and 34″ by virtue of penetrating through the inter-level dielectric layer 38 and the capping layer 36.

When fabricating the semiconductor structure whose schematic cross-sectional diagram is illustrated in FIG. 13A from the semiconductor structure whose schematic cross-sectional diagram is illustrated in FIG. 12A, the capping layer 36 and the inter-level dielectric layer 38 are first formed as blanket layers, which as a layered structure are etched to form apertures that expose the contact vias 34′ and 34″. The apertures are then filled and planarized to form the supplemental contact vias 40′ and 40″.

FIG. 13B shows a schematic plan-view diagram corresponding with the semiconductor structure whose schematic cross-sectional diagram is illustrated in FIG. 13A.

FIG. 13B shows the inter-level dielectric layer 38 having supplemental contact vias 40′ (i.e., peripheral source/drain contacts), 40″ (i.e., central source/drain region contacts) and 40′″ (i.e., gate contact) located and formed therein. FIG. 13B also illustrates the contact vias 34′ and 34″ that sandwich the spacer layers 28′ that in turn sandwich the gate electrode that comprises the silicide layer 32″, the supplemental gate material layer 22″ and the gate material layer 16″, all of which are located beneath the inter-level dielectric layer 38.

FIG. 12A and FIG. 12B most particularly illustrate schematic cross-sectional and plan-view diagrams of a semiconductor structure in accordance with a preferred embodiment of the invention. The semiconductor structure includes a field effect device that includes a spacer shaped gate electrode 32″/22″/16″. The field effect device also includes an annular contact via 34′ that surrounds the gate electrode 32″/22″/16″ and also has a spacer shape. The semiconductor structure also includes a non-annular contact via 34″ that is surrounded by the annular gate electrode 32″/22″/16″ and does not have a spacer shape.

The semiconductor structure whose schematic cross-sectional diagram is illustrated in FIG. 12A may be fabricated using a self-aligned method for forming all outer lying layers with respect to a sacrificial layer that serves the purpose of a mandrel layer. Thus, the semiconductor structure of FIG. 12A may be fabricated efficiently with improved overlap registry.

The preferred embodiment of the invention is illustrative of the invention rather than limiting of the invention. Revisions and modifications may be made to methods, materials, structures and dimensions of a semiconductor structure in accordance with the preferred embodiment, while still providing an embodiment in accordance with the invention, further in accordance with the accompanying claims.

What is claimed is:

1. A method for fabricating a semiconductor structure comprising:
forming a gate electrode annularly surrounding a sacrificial layer located over a semiconductor substrate;
removing the sacrificial layer from over the semiconductor substrate to leave remaining the annular gate electrode;
forming a first source/drain region within the semiconductor substrate outside of the annular gate electrode and a second source/drain region inside the annular gate electrode; and
forming an annular contact via contacting the first source/drain region and surrounding the annular gate electrode.

2. The method of claim 1 wherein the forming the annular gate electrode forms an annular spacer shaped gate electrode.

3. The method of claim 1 wherein the forming the annular contact via forms an annular spacer shaped contact via.

4. The method of claim 1 wherein the forming the annular contact via simultaneously forms a second contact via upon the second source/drain region.

5. The method of claim 4 wherein the second contact via is not annular.

6. The method of claim 1 wherein the forming the annular gate electrode comprises an anisotropic etch method to provide a spacer shaped annular gate electrode.

7. The method of claim 1 wherein the forming the annular contact via comprises an anisotropic etch method to provide a spacer shaped annular contact via.

8. The method of claim 1 wherein the forming the gate electrode annularly surrounding a sacrificial layer comprises:
forming a material stack on an active region of said semiconductor substrate, said material stack comprising, from bottom to top, a gate dielectric, a gate material layer and a sacrificial material;
forming a patterned photoresist atop the material stack;
removing exposed portions of the sacrificial material not protected by said patterned photoresist providing a patterned sacrificial material;
removing the patterned photoresist;
forming a supplemental gate material layer atop exposed surfaces of the gate dielectric and on vertical sidewalls and atop the patterned sacrificial material; and
anistropically etching the supplemental gate material layer.

9. The method of claim 8 wherein said anistropically etching comprises use of an etchant gas composition.

10. The method of claim 1 wherein said removing the sacrificial layer from over the semiconductor substrate comprises wet etching or dry etching.

11. A method for fabricating a semiconductor structure comprising:
forming a material stack on an active region of said semiconductor substrate, said material stack comprising, from bottom to top, a gate dielectric, a gate material layer and a sacrificial material;
forming a patterned photoresist atop the material stack;
removing exposed portions of the sacrificial material not protected by said patterned photoresist providing a patterned sacrificial material;
removing the patterned photoresist;
forming a supplemental gate material layer atop exposed surfaces of the gate dielectric and on vertical sidewalls and atop the patterned sacrificial material;
anistropically etching the supplemental gate material layer providing at least one spacer shaped gate electrode;
removing exposed portions of the gate dielectric not protected by said at least one spacer shaped gate electrode;
removing remaining portions of sacrificial material from over the semiconductor substrate;
forming a first source/drain region within the semiconductor substrate outside of at least one spacer shaped gate electrode and a second source/drain region inside the at least one spacer shaped gate electrode; and
forming an annular contact via contacting the first source/drain region and surrounding the at least one spacer shaped gate electrode.

12. The method of claim 11 wherein the forming the annular contact via forms an annular spacer shaped contact via.

13. The method of claim 11 wherein the forming the annular contact via simultaneously forms a second contact via upon the second source/drain region.

14. The method of claim 13 wherein the second contact via is not annular.

15. The method of claim 11 wherein the forming the annular gate electrode comprises an anisotropic etch method to provide a spacer shaped annular gate electrode.

16. The method of claim 11 wherein the forming the annular contact via comprises an anisotropic etch method to provide a spacer shaped annular contact via.

17. The method of claim 11 wherein said anistropically etching comprises use of an etchant gas composition.

18. The method of claim 11 wherein said removing the remaining sacrificial material from over the semiconductor substrate comprises wet etching or dry etching.
